(19) United States
(12) Patent Application Publication
(10) Pub. No.: US 2021/0375614 A1
(43) Pub. Date: Dec. 2, 2021

(54) NITRIDE SEMICONDUCTOR ELEMENT

(71) Applicant: ASAHI KASEI KABUSHIKI KAISHA, Tokyo (JP)

(72) Inventors: Kosuke SATO, Tokyo (JP); Motoaki IWAYA, Nagoya-shi (JP)

(73) Assignee: ASAHI KASEI KABUSHIKI KAISHA, Tokyo (JP)

(21) Appl. No.: 17/205,361

(22) Filed: Mar. 18, 2021

(30) Foreign Application Priority Data
May 28, 2020 (JP) 2020-093406
Jan. 28, 2021 (JP) 2021-012414

(51) Int. Cl. H01L 21/02

(52) U.S. Cl. CPC H01L 21/0254; H01L 21/02505

(57) ABSTRACT

Provided is a nitride semiconductor element capable of stably withstand being driven at high current density without becoming insulated. The nitride semiconductor element includes an active layer and an AlGaN layer formed above the active layer and formed of AlGaN, the AlGaN containing Mg and having an Al composition ratio decreasing in a direction away from the active layer, and the Al composition ratio being larger than 0.2, in which the AlGaN layer includes a first AlGaN region in which a compositional gradient a1 of the Al composition ratio is larger than 0 Al %/nm and smaller than 0.22 Al %/nm, and a concentration b1 of the Mg in the AlGaN layer is larger than 0 cm⁻³ and smaller than 7.0×10¹⁹×a1-2.0×10¹⁸ cm⁻³.

### TECHNICAL FIELD

The present disclosure relates to a nitride semiconductor element.

### BACKGROUND ART

Conventionally, as light emitting diodes (LEDs) and laser diodes (LDs), nitride semiconductor elements have been used. When nitride semiconductor elements are light emitting diodes (LED), the light emitting diodes have a small element area, like micro LEDs. In this case, to obtain high output, the elements are required that are capable of withstanding being driven at high current density. Additionally, when nitride semiconductor elements are laser diodes (LDs), the elements need to be able to withstand being driven at high current density exceeding 1 kA/cm² in order to achieve laser oscillation. Then, for example, there have been proposed nitride semiconductor elements including a p-type clad layer formed of AlGaN in which an Al composition decreases in a thickness direction (for example, PTL 1: JP 2018-098401 A). PTL 1 discloses that compositionally grading the Al composition in the p-type AlGaN clad layer lowers a threshold current density and a threshold voltage for laser oscillation.

### SUMMARY

However, even when the Al composition in the p-type AlGaN clad layer is graded, the nitride semiconductor element may become insulated or may have high resistance depending on the composition of AlGaN in the p-type AlGaN clad layer.

It is an object of the present disclosure to provide a nitride semiconductor element capable of stably withstanding being driven at high current density.

In order to achieve the above object, a nitride semiconductor element according to one aspect of the present invention includes an active layer and an AlGaN layer formed above the active layer and formed of AlGaN, the AlGaN containing Mg and having an Al composition ratio decreasing in a direction away from the active layer, and the Al composition ratio being larger than 0.2, in which the AlGaN layer includes a first AlGaN region in which a compositional gradient a1 of the Al composition ratio is larger than 0 Al %/nm and smaller than 0.22 Al %/nm, and a concentration b1 of the Mg in the AlGaN layer is larger than 0 cm⁻³ and smaller than 7.0×10¹⁹×a1-2.0×10¹⁸ cm⁻³.

According to the one aspect of the present disclosure, there can be provided a nitride semiconductor element capable of stably withstand being driven at high current density without becoming insulated or having high resistance.

### BRIEF DESCRIPTION OF DRAWINGS

FIG. 1 is a perspective view illustrating a configuration example of a nitride semiconductor element according to a first embodiment of the present disclosure;

FIG. 2 is a graph illustrating an Al composition ratio of a part of the nitride semiconductor element according to the first embodiment of the present disclosure;

FIG. 3 is a graph illustrating a preferable Mg concentration in the nitride semiconductor element according to the first embodiment of the present disclosure;

FIG. 4 is a perspective view illustrating a configuration example of a nitride semiconductor element according to a second embodiment of the present disclosure;

FIG. 5 is a graph illustrating an Al composition ratio of a part of the nitride semiconductor element according to the second embodiment of the present disclosure;

FIG. 6 is a graph illustrating current-voltage characteristics in nitride semiconductor element samples 1 to 4 in Example of the present disclosure; and

FIG. 7 is a graph illustrating current-voltage characteristics in nitride semiconductor element samples 5 to 7 in Example of the present disclosure.

### DESCRIPTION OF EMBODIMENTS

Hereinafter, nitride semiconductor elements according to present embodiments will be described through embodiments. However, the following embodiments are not intended to limit the invention according to the scope of the claims. Additionally, not all of the combinations of features described in the embodiments are always essential for the solving means of the invention.

### 1. First Embodiment

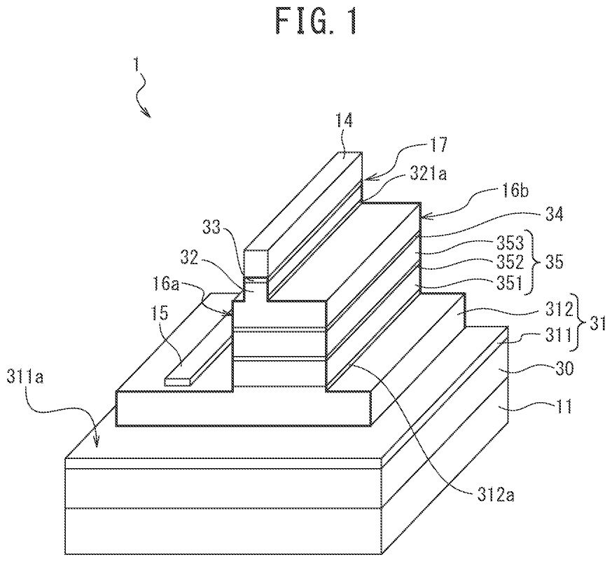

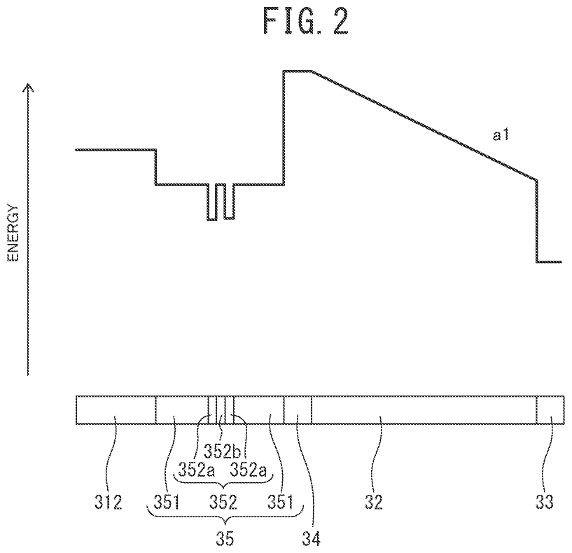

A nitride semiconductor element 1 according to a first embodiment will be described below with reference to FIGS. 1 and 2.

The nitride semiconductor element 1 is a laser diode capable of emitting ultraviolet light. The nitride semiconductor element 1 can emit ultraviolet laser light by current injection. The nitride semiconductor element 1 can obtain light emission in a UVB region with wavelengths of from 280 to 320 nm.

### [Entire Configuration of Nitride Semiconductor Element]

The configuration of the nitride semiconductor element 1 will be described with reference to FIGS. 1 and 2.

As illustrated in FIG. 1, the nitride semiconductor element 1 includes a substrate 11, a nitride semiconductor active layer (an example of an active layer) 352 provided above the substrate 11, an AlGaN layer 32 provided above the nitride semiconductor active layer 352 and having an Al composition ratio larger than 0.2, and a second nitride semiconductor layer 33 covering an upper surface of the AlGaN layer 32. The nitride semiconductor element 1 has a configuration in which an AlN layer (an example of a base layer) 30, a first nitride semiconductor layer 31, a light emitting portion 35 including the nitride semiconductor active layer 352, an electron block layer 34, the AlGaN layer 32, and the second nitride semiconductor layer 33 are stacked in this order on or above the substrate 11. The nitride semiconductor element 1 also includes a first electrode 14 provided in contact with the second nitride semiconductor layer 33 and a second electrode 15 provided in contact with a part of the first nitride semiconductor layer 31.

The following is a detailed description of each portion that forms the nitride semiconductor element 1.

### <AlGaN Layer>

As illustrated in FIG. 2, the AlGaN layer 32 is formed of AlGaN having an Al composition ratio decreasing in a direction away from the nitride semiconductor active layer 352, the Al composition ratio being larger than 0.2. In the nitride semiconductor element 1 of the present embodiment, the AlGaN layer 32 that has a single layer structure (an example of a first AlGaN region) will be described. The nitride semiconductor element 1 including such an AlGaN layer 32 is, for example, an ultraviolet light laser diode that emits ultraviolet B wave.

The AlGaN layer 32 contains magnesium (hereinafter may be referred to as Mg), and is formed of AlGaN in which the Al composition ratio decreases in the direction away from the nitride semiconductor active layer 352. The AlGaN layer 32 is a p-type semiconductor doped with Mg as an impurity. In the AlGaN layer 32, a compositional gradient a1 of the Al composition ratio is larger than 0 Al %/nm and smaller than 0.22 Al %/nm. In other words, the compositional gradient a1 of the Al composition ratio is represented by 0<a1<0.22. An Al composition ratio x1 of the AlGaN layer 32 may decrease at a constant rate of change in an entire area in a thickness direction of the AlGaN layer 32 or may decrease at a different rate of change depending on the position as long as the Al composition ratio x1 is within the above range.

In addition, the Al composition ratio x1 may be configured to vary in multiple stages by including a region where the Al composition ratio x1 once becomes constant in a midway portion of the thickness direction of the AlGaN layer 32. In this case, a compositional gradient of the Al composition ratio x1 in the entire thickness direction of the AlGaN layer 32 is preferably within the above-mentioned range. Specifically, a value obtained by dividing a difference between an initial end Al composition ratio of the AlGaN layer 32 (an Al composition ratio of a boundary on the electron block layer 34 side) and a final end Al composition ratio thereof (an Al composition ratio of a boundary on the second nitride semiconductor layer 33 side) by a thickness of the AlGaN layer 32 is preferably larger than 0 Al %/nm and smaller than 0.22 Al %/nm.

When the composition ratio of Al is x1, the AlGaN layer 32 is formed of Alₓ₁Ga₍₁₋ₓ₁₎N. The Al composition ratio x1 in the AlGaN layer 32 is, for example, preferably 0.2<x1≤1.0, more preferably 0.3≤x1≤1.0, and still more preferably 0.4≤x1≤1.0. In other words, the Al composition ratio x1 in the AlGaN layer 32 may vary from 1.0 up to almost 0.2 in the direction away from the nitride semiconductor active layer 352, more preferably from 1.0 up to 0.3, and still more preferably from 1.0 up to 0.4. This allows for high current flow in the nitride semiconductor element 1, and allows the element 1 to be an element capable of withstanding being driven at high current density.

Here, when the Al composition ratio of the AlGaN in the AlGaN layer 32 is equal to or more than 0.2 (i.e., 20% or more), activation energy increases in the p-type semiconductor doped with Mg as an impurity, which makes p-type doping difficult. For example, when p-Al_{0.2}Ga_{0.8}N is doped with Mg at a concentration of 2×10²⁰ cm⁻³, the hole density to be obtained is estimated to be 4×10¹⁷ cm⁻³. When p-Al_{0.4}Ga_{0.6}N is doped with Mg, the hole density to be obtained is estimated to be 9×10¹⁶ cm⁻³. In general, to drive a vertical electric nitride semiconductor element using AlGaN (such as a light emitting diode (LED) or a laser diode (LD)), a carrier density in a conductive semiconductor is required to be at least 1×10¹⁷ cm⁻³. Therefore, in vertical electric nitride semiconductor elements using AlGaN having an Al composition ratio of 0.4 or more, it is hard to form a p-type semiconductor even by doping with Mg as an impurity, so that it may be difficult to drive them.

In the nitride semiconductor element 1 according to the present disclosure, the Al composition ratio of the AlGaN layer 32 is larger than 0.2, and particularly, even when the Al composition ratio is 0.4 or more, p-type doping is facilitated by polarization doping that allows holes to be generated by grading the Al composition in the thickness direction. Thus, the nitride semiconductor element 1 is easy to drive.

On the other hand, in a region with an Al composition ratio of 0.2 or less, a conductive p-type semiconductor can be formed by doping with Mg as an impurity, so that the effect of making the semiconductor p-type by polarization doping by grading of the Al composition is very small.

As described above, in the AlGaN layer 32, it is preferable to make a p-type semiconductor by polarization doping that allows for the generation of holes by grading of the Al composition.

Additionally, when the nitride semiconductor element 1 is an element that emits ultraviolet light having a wavelength of less than 320 nm, the Al composition ratio of AlGaN used as the nitride semiconductor active layer 352 needs to be larger than 0.2. Here, when the nitride semiconductor element 1 is a laser diode (LD), it is necessary to set the Al composition ratio of the AlGaN layer 32 larger than the Al composition ratio of the nitride semiconductor active layer 352 (and a waveguide layer) in order to confine light in the waveguide layer (unillustrated). Due to that, the Al composition needs to be graded in the AlGaN layer 32 formed of AlGaN having an Al composition ratio of larger than 0.2.

Furthermore, when the nitride semiconductor element 1 is an element that emits ultraviolet light having a wavelength of 300 nm or less, it is necessary to set the Al composition ratio of the AlGaN layer 32 larger than 0.4 because of the above-described reason. Even in this case, since the element 1 includes the AlGaN layer 32 formed of the AlGaN having the Al composition ratio of larger than 0.4, the Al composition needs to be graded, as in the nitride semiconductor element 1 that emits ultraviolet light having a wavelength of less than 320 nm.

Here, when using a thin-film growth apparatus to form the AlGaN layer 32 in which the Al composition is continuously graded from AlGaN having a large Al composition ratio to AlGaN having a small Al composition ratio, it is not preferable to form the AlGaN layer 32 while varying growth apparatus parameters (temperature, pressure, and III/V raw material ratio) other than a group III raw material ratio. Particularly, an amount of Mg absorbed significantly depends on the growth apparatus parameters, due to which varying an undesirable parameter makes it extremely difficult to control the amount of Mg absorbed into the AlGaN layer 32. Therefore, in order to make the control of absorption of Mg as unnecessary as possible and reduce change in the Al composition in the AlGaN layer 32 (reduce the range of change in the Al composition), it is preferable that the Al composition ratio is larger than 0.2. In order to grow the AlGaN layer 32 more as designed, more preferably, the Al composition ratio is larger than 0.4 so that the change in the Al composition in the AlGaN layer 32 becomes small.

For example, when the Al composition ratio of the AlGaN layer 32 is larger than 0.2 and a maximum Al composition ratio of the AlGaN layer 32 is larger than 0.2 and smaller than 0.6, it is possible to form the AlGaN layer 32 having a constant Al composition change rate without varying growth conditions other than the group III raw material ratio.

Additionally, when the Al composition ratio of the AlGaN layer 32 is larger than 0.4 and the maximum Al composition ratio of the AlGaN layer 32 is larger than 0.4 and not larger than 1, it is possible to form the AlGaN layer 32 having a constant Al composition change rate without varying growth conditions other than the group III raw material ratio.

Thus, when the Al composition ratio of the AlGaN layer 32 is larger than 0.4, the maximum Al composition ratio of the AlGaN layer 32 can be increased, so that design flexibility can be expanded into a region with large Al composition. This allows for shortening of wavelength, particularly, in ultraviolet light emitting elements, and is particularly important for those with short wavelength.

In other words, when the Al composition ratio of the AlGaN layer 32 is larger than 0.4, the AlGaN layer 32, which is a p-type semiconductor in the ultraviolet light emitting element, can be formed as designed.

On the other hand, when the Al composition ratio is smaller than 0.2 and the maximum Al composition ratio of the AlGaN layer 32 is larger than 0.5, it is necessary to vary respective parameters including the parameters (temperature, pressure, and III/V raw material ratio) other than the group III raw material ratio during a thin film growth in order to make constant the Al composition change rate in the AlGaN layer 32. In this case, when the thin film growth is interrupted, there occur degradation of semiconductor quality such as an uneven rate of change in the Al composition and a change in thin-film surface composition.

In addition, the AlGaN layer 32 contains Mg. The Mg serves as an impurity for generating holes in the AlGaN layer 32.

A concentration b1 of the Mg in the AlGaN layer 32 is larger than 0 cm⁻³ and smaller than 7.0×10¹⁹×a1-2.0×10¹⁸ cm⁻³. When the AlGaN layer 32 does not contain Mg or contains a low concentration of Mg, the nitride semiconductor element 1 may become insulated even when the Al composition ratio is graded in the AlGaN forming the AlGaN layer 32. When the compositional gradient a1 of the Al composition ratio of the AlGaN layer 32 is within the range of 0<a1<0.22, current flows more easily when the Mg concentration is lower than an Mg concentration in a typical p-type semiconductor. Here, an optimal value of an Mg concentration in typical p-type AlGaN is, for example, within a range of from 1.0×10¹⁹ cm⁻³ to 3.0×10¹⁹ cm⁻³. The present inventors have found that the reason is that containing Mg creates a donor defect (Nd), then the donor defect generates electrons, and the electrons cancel out holes generated by polarization doping. When the Mg concentration b1 is larger than 0 cm⁻³ and smaller than 7.0×10¹⁹×a1-2.0×10¹⁸ cm⁻³, the holes are cancelled out by the electrons in a region where the holes are generated by the polarization doping, which can suppress insulation.

In addition, the reason why the Mg concentration is larger than 0 cm⁻³ is to suppress insulation by cancelling out electrons generated in the AlGaN layer 32 due to lattice relaxation during the thin film growth by holes generated by activation of the Mg impurity. When a lower layer and an upper layer of the AlGaN layer 32 having the graded Al composition are different in a-axis lattice constant, particularly it is a lattice relaxation state where the a-axis lattice constant of the upper layer is larger than the a-axis lattice constant of the lower layer, it indicates that there is a portion where compressive stress, which is a condition for generating holes by polarization doping, does not work. In this case, no holes are generated at the portion where the compressive stress does not work, which therefore substantially requires the generation of holes by inclusion of an Mg impurity. Thus, preferably, the AlGaN layer 32 contains Mg in the above-mentioned concentration range.

In order to calculate an optimum amount of Mg in the AlGaN, a theoretical calculation was performed using thin-film simulation software SiLENSe (manufactured by STR Japan K. K). The gradient of the Al composition ratio and the Mg concentration in the AlGaN layer 32 were set to preferable ranges by simulation of the following procedure.

Here, the stacking structure of a nitride semiconductor element input in the thin-film software is as follows. The following structure is described in order, starting from lower layers.

### (Structure)

Lower clad layer: AlGaN, Al composition ratio 55%, thickness 3 μm, n-type impurity (Si)-doped.
Light emitting layer

Lower guide layer: AlGaN, Al composition ratio 45%, thickness 150 nm, undoped.

Well layer: AlGaN, Al composition ratio 35%, thickness 4 nm, undoped.

Barrier layer: AlGaN, Al composition ratio 45%, thickness 8 nm, undoped.

Well layer: AlGaN, Al composition ratio 35%, thickness 4 nm, undoped.

Upper guide layer: AlGaN, Al composition ratio 45%, thickness 150 nm, undoped.
Electron block layer: AlGaN, Al composition ratio the same as the initial end composition ratio of the AlGaN layer, thickness 20 nm, undoped.
AlGaN layer (two-layer structure)

First AlGaN region: AlGaN, Al composition ratio x→45% (x varies), compositional gradient a1 of Al composition ratio, thickness 260 nm, p-type impurity (Mg)-doped, n-type impurity (Si)-doped.

Second AlGaN region: AlGaN, Al composition ratio 45→0%, thickness 75 nm, p-type impurity (Mg)-doped, n-type impurity (Si)-doped.

Second nitride semiconductor layer: GaN, thickness 10 nm, p-type impurity (Mg)-doped.

Here, the stacking structure of the nitride semiconductor element for the simulation described above includes the AlGaN layer including the two-layer structure (the first AlGaN region and the second AlGaN region) different in Al composition ratio gradient. In the nitride semiconductor element 1 according to the present embodiment, the Al composition ratio gradient of the first AlGaN region of the AlGaN layer of the nitride semiconductor element input to the thin-film simulation software is set as the compositional gradient a1 of the Al composition ratio of the AlGaN layer 32. Additionally, in order to reflect generation of Mg impurity-derived donor defects in the first AlGaN region and the second AlGaN region in the simulation, there was used a hypothesis that an n-type impurity assumed to be Si was contained by the following method.

### (Simulation Procedure)

(1) First, the thin-film simulation software SiLENSe was used to perform a band calculation at 0 V (non-electric field) of each layer of the thin-film structure. In this case, an n-type impurity concentration was set to 1/10 of an acceptor impurity concentration (corresponding to Mg concentration). As a donor impurity concentration, an amount of 10% of a p-type impurity doping amount was set based on a description in “Overview of carrier compensation in GaN layers grown by MOVPE: toward the application of vertical power devices (Tetsuo Narita et al, Japanese Journal of Applied Physics 59, SA0804, 2020).

(2) Next, hole density data in the center of a thickness direction of the first AlGaN region (a position at 130 nm away from a lower surface of the second AlGaN region) was extracted.

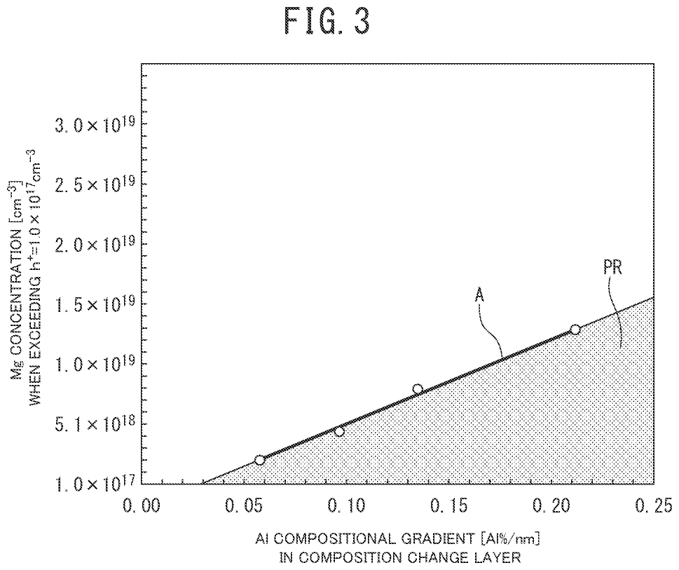

(3) A graph was created with a vertical axis representing the acceptor impurity concentration (the concentration set in (1)) at which the hole density extracted in (2) becomes a value exceeding 1.0×10¹⁷ cm⁻³ and a horizontal axis representing the compositional gradient a1 [Al %/nm] of the Al composition ratio of the first AlGaN region. Here, FIG. 3 is a graph plotted with circles on a relationship between the compositional gradient a1 of the Al composition ratio and the acceptor impurity concentration obtained by the simulation.

(4) An approximate equation was obtained by approximating a straight line showing the relationship between the compositional gradient a1 of the Al composition ratio and the acceptor impurity concentration obtained in (3). By approximating the plot illustrated in FIG. 3, there was obtained an approximate equation A: Mg concentration b1=7.0×10¹⁹×a1-2.0×10¹⁸. Finally, as illustrated in FIG. 3, a range where the hole density exceeds 1.0×10¹⁷ cm⁻³ based on the approximate equation A obtained in (4) is considered to be a preferable Mg concentration range PR. In other words, when the Mg concentration b1 in the first AlGaN region is larger than 0 cm⁻³ and smaller than 7.0×10¹⁹×a1-2.0×10¹⁸ cm⁻³, the hole density (indicated by h⁺ on the vertical axis in the graph) exceeds 1.0×10¹⁷ cm⁻³. This allows obtaining of the amount of holes required to drive a nitride semiconductor element that generally has high current density, so that insulation is unlikely to occur.

It is also preferable that, on an upper end surface (a boundary with the second nitride semiconductor layer 33) of the AlGaN layer 32, the AlGaN is lattice-relaxed from a lower end surface (a boundary with the electron block layer 34) of the AlGaN layer 32. Here, the expression “on the upper end surface of the AlGaN layer 32, the AlGaN is lattice-relaxed from the lower end surface of the AlGaN layer 32” means that an a-axis lattice constant c2 of the upper end surface of the AlGaN layer 32 is larger than an a-axis lattice constant c1 of the lower end surface of the AlGaN layer 32. When lattice relaxation occurs in the AlGaN layer 32, a hole gas is easily generated in a region that is near the lower end surface of the AlGaN layer 32 and that has a relatively large Al composition ratio, whereas electrons are generated in a region that is near the upper end surface of the AlGaN layer 32 and where the above-described lattice relaxation has occurred. However, by containing a predetermined amount of Mg in the AlGaN layer 32 to activate the Mg, the generated electrons are cancelled out by the holes generated in the AlGaN layer 32, thereby allowing current to flow easily. Accordingly, in the AlGaN layer 32 where the a-axis lattice constant c2 of the upper end surface is larger than the a-axis lattice constant c1 of the lower end surface and electron gas is easily generated, containing the predetermined amount of Mg can further improve the effect of facilitating current flow. It is also possible to suppress the occurrence of cracks during thin-film growth due to more stress than necessary in a thin film by lattice relaxation.

Preferably, the AlGaN layer 32 has a thickness of from more than 0 nm to less than 400 nm. When the thickness of the AlGaN layer 32 is less than 400 nm, the AlGaN layer 32 has low resistance, which suppresses increase in the amount of heat generation due to increased drive voltage, so that breakdown of the nitride semiconductor element 1 is unlikely to occur.

When the nitride semiconductor element 1 is a laser diode, the thickness of the AlGaN layer 32 is preferably from 150 nm to less than 400 nm, and more preferably from 200 nm to less than 400 nm. For example, the AlGaN layer 32 has a thickness of 260 nm.

Alternatively, when the nitride semiconductor element 1 is a light emitting diode (LED) or the like, the AlGaN layer 32 may have a thickness of more than 0 nm to less than 150 nm. Even when the nitride semiconductor element 1 is a laser diode requiring light confinement, high current can be caused to flow while the AlGaN layer 32 is thin. On the other hand, the nitride semiconductor element 1 that is a light emitting diode does not require light confinement. Thus, there can be obtained a favorable element that achieves high current density even when the AlGaN layer 32 is thinner than in the case of a laser diode.

The AlGaN layer 32 also may include a protruding portion on a surface thereof facing the second nitride semiconductor layer 33. In this case, the Al composition ratio x1 may be graded from a side of the AlGaN layer 32 facing the electron block layer 34 toward a leading end of the protruding portion. Including the protruding portion on the AlGaN layer 32 has the effect of improving current density when electrons are injected from the first electrode 14. In addition, including the protruding portion on the AlGaN layer 32 can increase a contact area between the AlGaN layer 32 and the second nitride semiconductor layer 33, which can reduce series resistance and pseudo energy barrier, thus allowing for reduced Schottky component and improved carrier injection efficiency.

Here, the protruding portion provided on the AlGaN layer 32 is not formed corresponding to an unevenness of any layer positioned lower than the AlGaN layer 32. Specifically, the thickness of a portion of the AlGaN layer 32 provided with the protruding portion is larger than the thickness of a portion of the AlGaN layer 32 provided with no protruding portion by the amount of a height of the protruding portion. Therefore, even when a projecting portion is formed on any layer lower than the AlGaN layer 32, the protruding portion is formed at a position different from that of the projecting portion of the lower layer in plan view or in a cycle different from that of the projecting portion thereof.

### <Second Nitride Semiconductor Layer>

The second nitride semiconductor layer 33 is a region that is further away from the nitride semiconductor active layer 352 than the AlGaN layer 32 is, and is a cover layer covering the upper surface of the AlGaN layer 32. The second nitride semiconductor layer 33 is formed of AlGaN or GaN having an Al composition ratio smaller than that in the AlGaN layer 32. Specifically, the second nitride semiconductor layer 33 is formed of Alₓ₃Ga₍₁₋ₓ₃₎N (0≤x3<x).

When a top layer of the second nitride semiconductor layer 33 is formed of p-type GaN (p-GaN), a contact resistance with the first electrode 14 arranged on the second nitride semiconductor layer 33 can be reduced, and a wavelength range of ultraviolet light to which the nitride semiconductor element 1 can respond is widened. This is because by using p-type GaN as the second nitride semiconductor layer 33, the Al composition ratio of the AlGaN in the AlGaN layer 32 can be designed widely.

The second nitride semiconductor layer 33 may have a configuration in which a plurality of layers are stacked. In this case, the above-mentioned Al composition ratio of the second nitride semiconductor layer 33 indicates the Al composition ratio of a top surface layer, i.e., a surface in contact with the first electrode 14.

The second nitride semiconductor layer 33 is a p-type semiconductor layer doped with Mg at a concentration of, for example, 3×10¹⁹ cm⁻³ to make it p-type.

The concentration of the dopant may be constant or uniform in a direction perpendicular to the substrate 11, and may be constant or uniform in an in-plane direction of the substrate 11.

The second nitride semiconductor layer 33 may have a structure in which the Al composition ratio of the AlGaN is graded. For example, the second nitride semiconductor layer 33 may have a layer structure in which the Al composition ratio of the AlGaN decreases continuously or stepwise from a minimum value of the Al composition ratio of the AlGaN layer 32. When the second nitride semiconductor layer 33 has the layer structure, the second nitride semiconductor layer 33 may be an undoped layer.

The second nitride semiconductor layer 33 may have a stacking structure that further includes a layer having a high doping concentration as a top layer. The second nitride semiconductor layer 33 may have a stacking structure including two or more layers. In this case, preferably, the Al composition ratio is made smaller toward an upper layer in order to efficiently transport carriers to the nitride semiconductor active layer 352.

The second nitride semiconductor layer 33 has a thickness of preferably from more than 10 nm to less than 10 μm, more preferably from 200 nm to less than 10 μm, and still more preferably from 500 nm to 5 μm. When the thickness of the second nitride semiconductor layer 33 is more than 10 nm, the unevenness of the surface of the AlGaN layer 32 can be relatively uniformly covered, thereby improving adhesion between the AlGaN layer 32 and the second nitride semiconductor layer 33 provided on the upper surface of the AlGaN layer 32. Specifically, it is possible to suppress an uncovered part of the second nitride semiconductor layer 33 from being formed on an interface between the AlGaN layer 32 and the second nitride semiconductor layer 33. This can improve current density. In addition, when holes are injected from the first electrode 14, current concentration onto a part of the AlGaN layer 32 can be suppressed, and current can be uniformly injected from the upper surface of the AlGaN layer 32 (the surface facing the second nitride semiconductor layer 33). Additionally, when the thickness of the second nitride semiconductor layer 33 is more than 0 nm, the AlGaN layer 32 and the first electrode 14 are connected with low resistance via the second nitride semiconductor layer 33.

Alternatively, when the thickness of the second nitride semiconductor layer 33 is less than 10 μm, cracking is unlikely to occur during formation of the AlGaN layer 32, which is therefore preferable.

Furthermore, having the thickness of the second nitride semiconductor layer 33 within the above range can suppress three-dimensional growth due to lattice relaxation during growth of the second nitride semiconductor layer 33, thereby enabling flattening of the surface of the second nitride semiconductor layer 33. This can stabilize contactability between the second nitride semiconductor layer 33 and the first electrode 14, whereby the nitride semiconductor element 1 can achieve high reproducibility and low drive voltage.

### <Ridge Semiconductor Layer>

A ridge semiconductor layer 17 is formed by including a partial portion of the AlGaN layer 32. The ridge semiconductor layer 17 includes a protruding region 321a formed on the AlGaN layer 32, the AlGaN layer 32, and the second nitride semiconductor layer 33. Forming the ridge semiconductor layer 17 at the partial portion of the AlGaN layer 32 suppresses the carriers injected from the first electrode 14 from diffusing in a horizontal direction of the substrate 11 in the ridge semiconductor layer 17. This controls light emitted by the nitride semiconductor active layer 352 to a region located below the ridge semiconductor layer 17 (i.e., a region located below the protruding region 321a of the AlGaN layer 32). As a result, the nitride semiconductor element 1 can achieve high current density, allowing for reduced laser oscillation threshold.

As described above, roles of the ridge semiconductor layer 17 are the current concentration and the confinement of light in the horizontal direction of the substrate 11. Therefore, the ridge semiconductor layer 17 does not necessarily have to be formed only at the partial portion of the AlGaN layer 32. The ridge semiconductor layer 17 may include the light emitting portion 35, and may include the entire AlGaN layer 32. Alternatively, the ridge semiconductor layer 17 does not have to be formed. When the ridge semiconductor layer 17 is not formed, the AlGaN layer 32 is formed with the same area as that of the AlGaN layer 32. Additionally, the first electrode 14 (details thereof will be described later) may be designed to have appropriate width and length such that the amount of current injection is suppressed.

As described above, the ridge semiconductor layer 17 is biased to the second electrode 15 side. Arranging the ridge semiconductor layer 17 close to the second electrode 15 shortens a path of current flowing through the nitride semiconductor element 1, which can therefore reduce a resistance value of the current path formed in the nitride semiconductor element 1. This can achieve reduced drive voltage of the nitride semiconductor element 1. However, it is preferable that the protruding region 321a and the ridge semiconductor layer 17 are 1 μm or more away from mesa edges (edges of a region of the AlGaN layer 32 excluding the protruding region 321a) from the viewpoint of lithographic reproducibility. The protruding region 321a and the ridge semiconductor layer 17 may be formed to be biased to a centrally located side.

### <Substrate>

Examples of the substrate 11 include Si, SiC, MgO, Ga₂O₃, Al₂O₃, ZnO, GaN, InN, AlN, and mixed crystals thereof. The substrate 11 serves to support an upper layer thin film, improve crystallinity, and furthermore dissipate heat to the outside. Therefore, as the substrate 11, it is preferable to use an AlN substrate capable of growing AlGaN with high quality and having high thermal conductivity. A growth surface of the substrate is favorably a commonly used +c-plane AlN because of low cost, but may be a −c-plane AlN, a semi-polar plane substrate, or a non-polar plane substrate. From the viewpoint of increasing the effect of polarization doping, a +c-plane AlN is preferable.

The substrate 11 preferably has a quadrangular thin plate-like shape in terms of assembly, but is not limited to such a configuration. Additionally, the off-angle of the substrate 11 is preferably larger than 0 degrees and smaller than 2 degrees from the viewpoint of growing a high quality crystal.

The thickness of the substrate 11 is not particularly limited as long as it is intended to stack an AlGaN layer on an upper layer thereof, but a thickness of from 1 μm to 50 μm is preferable. In addition, although the crystal quality of the substrate 11 is not particularly limited, threading dislocation density is preferably 1×10⁹ cm⁻² or less, and more preferably 1×10⁸ cm⁻² or less. This allows for formation of a thin film element having high light emission efficiency above the substrate 11.

### <AlN Layer>

The AlN layer 30 is formed further away from the nitride semiconductor active layer 352 than the first nitride semiconductor layer 31 is, and is formed on the entire surface of the substrate 11.

The AlN layer 30 is small in lattice constant difference and thermal expansion coefficient difference from the first nitride semiconductor layer 31, and can grow a less defective nitride semiconductor layer on the AlN layer 30. The AlN layer 30 also can grow the first nitride semiconductor layer 31 under compressive stress, and can suppress the occurrence of cracks in the first nitride semiconductor layer 31. Therefore, even when the substrate 11 is formed of a nitride semiconductor such as AlN or AlGaN, a less defective nitride semiconductor layer can be grown above the substrate 11 via the AlN layer 30.

An impurity such as C, Si, Fe, or Mg may be mixed in the AlN layer 30.

When AlN is used as a material for forming the substrate 11, the AlN layer 30 and the substrate 11 will be formed of the same material, which makes unclear the boundary between the AlN layer 30 and the substrate 11. In the present embodiment, it is considered that when the substrate 11 is formed of AlN, the substrate 11 forms the substrate 11 and the AlN layer 30.

The AlN layer 30 has a thickness of, for example, several μm (for example, 1.6 μm), but the value is merely illustrative. Specifically, the thickness of the AlN layer 30 is preferably thicker than 10 nm and thinner than 10 μm. When the thickness of the AlN layer 30 is thicker than 10 nm, the crystallinity of AlN increases. Additionally, when the thickness of the AlN layer 30 is thinner than 10 μm, cracking is unlikely to occur in the AlN layer 30 formed by crystal growth on an entire wafer surface. Furthermore, more preferably, the AlN layer 30 is thicker than 50 nm and thinner than 5 μm. When the thickness of the AlN layer 30 is thicker than 50 nm, highly crystalline AlN can be produced with high reproducibility, and when the thickness of the AlN layer 30 is thinner than 5 μm, the occurrence of cracking in the AlN layer 30 is further suppressed.

The AlN layer 30 is formed thinner than the first nitride semiconductor layer 31, but this is merely illustrative. When the AlN layer 30 is thinner than the first nitride semiconductor layer 31, the first nitride semiconductor layer 31 can be made as thick as possible within a range where no cracks occur. In this case, the horizontal resistance of a thin-film layer stacked as the first nitride semiconductor layer 31 is reduced, whereby the nitride semiconductor element 1 can be driven at low voltage. Achieving low voltage driving of the nitride semiconductor element 1 can further suppress breakdown thereof when driven at high current density due to heat generation.

Note that the AlN layer 30 does not necessarily have to be provided.

### <First Nitride Semiconductor Layer>

The first nitride semiconductor layer 31 is a layer provided on a surface of the light emitting portion 35 including the nitride semiconductor active layer 352 on a side opposite to the AlGaN layer 32. The AlGaN layer 32 is an n-type semiconductor doped with an n-type impurity such as Si. The first nitride semiconductor layer 31 includes a first stacked portion 311 arranged above the substrate 11 and a second stacked portion 312 stacked on the first stacked portion 311. The second stacked portion 312 includes a protruding region 312a formed on a part of a surface of the second stacked portion 312. The second stacked portion 312 is arranged on a part of an upper surface 311a of the first stacked portion 311. Therefore, the upper surface 311a of the first stacked portion 311 includes a region formed without the second stacked portion 312 and a region formed with the second stacked portion 312. The region formed without the second stacked portion 312 on the upper surface 311a of the first stacked portion 311 is provided with the second electrode 15 connected with the first stacked portion 311.

Note that the second stacked portion 312 may be stacked on the entire part of the upper surface 311a of the first stacked portion 311.

The first stacked portion 311 and the second stacked portion 312 are both formed of AlGaN. The Al composition ratio of each of the first stacked portion 311 and the second stacked portion 312 may be the same or different. The Al composition ratio of the first nitride semiconductor layer 31 can be identified by energy dispersive X-ray spectroscopy (EDX) of a cross-sectional structure. The cross section of the first nitride semiconductor layer 31 can be observed by exposing the cross section along the a-plane of AlGaN using a focused ion beam (FIB) device. A transmission electron microscope is used as a method for observing the cross section. The observation magnification varies according to the thickness of a layer to be measured, and it is preferable to set the magnification so that scale bar levels of first nitride semiconductor layers 31 having different thicknesses are the same as each other. For example, when observing a first nitride semiconductor layer 31 having a thickness of 100 nm, the magnification is set to preferably approximately 100,000 times. Additionally, when the magnification to observe the first nitride semiconductor layer 31 having the thickness of 100 nm is approximately 100,000 times, a first nitride semiconductor layer 31 having a thickness of 1 μm is preferably observed at a magnification of approximately 10,000 times. In this way, the first nitride semiconductor layers 31 different in thickness can be observed at the same scale level.

The Al composition ratio can be defined as a ratio of the number of moles of Al to a sum of the numbers of moles of Al and Ga, and specifically can be defined using values of the numbers of moles of Al and Ga analyzed and quantified from EDX.

The first stacked portion 311 is formed of, for example, Alₓ₅Ga₍₁₋ₓ₅₎N (0<x5<1). The first stacked portion 311 may contain, for example, B or In other than Al and Ga as group III elements in AlGaN. However, defect formation and change in durability occur in a region including B or In, so that it is preferable to contain no group III elements other than Al and Ga.

Furthermore, the first stacked portion 311 may contain a group V element other than N, such as P, As, or Sb or an impurity such as C, H, F, O, Mg, or Si, in addition to AlGaN.

The second stacked portion 312 is formed of, for example, Alₓ₆Ga₍₁₋ₓ₆₎N (0≤x6≤1). An Al composition ratio x6 of the AlGaN forming the second stacked portion 312 may be the same as or smaller than an Al composition ratio x5 of the upper surface 311a of the first stacked portion 311. This can suppress the occurrence of a defect in a stacked interface between the first stacked portion 311 and the second stacked portion 312.

Additionally, the second stacked portion 312 may contain a group V element other than N, such as P, As, Sb, a group III element such as In or B, or an impurity such as C, H, F, O, Si, Cd, Zn, or Be, in addition to AlGaN.

In the present disclosure, the first stacked portion 311 and the second stacked portion 312 are n-type semiconductors. The first stacked portion 311 and the second stacked portion 312 are made n-type by doping AlGaN with, for example, Si at a concentration of 1×10¹⁹ cm⁻³. Impurity concentration may be uniform or non-uniform throughout the layer, may be non-uniform only in the thickness direction, or may be non-uniform only in the horizontal direction of the substrate.

The first stacked portion 311 and the second electrode 15 may be in direct contact or may connected via a different layer, like a tunnel junction. When the first nitride semiconductor layer 31 formed of an n-type semiconductor is connected with the second electrode 15 by a tunnel-junction, there is provided a p-type semiconductor between the first nitride semiconductor layer 31 and the second electrode 15. Therefore, the second electrode 15 is preferably formed of a material capable of forming an ohmic contact with the p-type semiconductor. Preferably, the second electrode 15 is, for example, a stacked electrode of Ni and Au or an electrode formed of an alloyed metal.

The second stacked portion 312 is an n-type semiconductor using +c-plane sapphire from the viewpoint of forming a PN diode with the AlGaN layer 32 that will be described later. The AlGaN layer 32 uses the AlGaN in which the Al composition ratio x1 decreases in the thickness direction of the AlGaN layer 32. Therefore, with the use of +c-plane sapphire as the second stacked portion 312, the AlGaN layer 32 becomes a p-type semiconductor due to polarization.

The thickness of the first stacked portion 311 is not particularly limited, but for example, preferably from 100 nm to 10 μm. When the thickness of the first stacked portion 311 is 100 nm or more, resistance of the first stacked portion 311 is reduced. When the thickness of the first stacked portion 311 is 10 μm or less, the occurrence of cracking during formation of the first stacked portion 311 is suppressed.

The thickness of the second stacked portion 312 is not particularly limited, but, for example, preferably from 100 nm to 10 μm. When the thickness of the second stacked portion 312 is 100 nm or more, resistance of the second stacked portion 312 is reduced. When the thickness of the second stacked portion 312 is 10 μm or less, the occurrence of cracking during formation of the second stacked portion 312 is suppressed.

### <Light Emitting Portion>

The light emitting portion 35 includes the nitride semiconductor active layer 352, a lower guide layer 351 provided on one surface of the nitride semiconductor active layer 352, and an upper guide layer 353 provided on an other surface of the nitride semiconductor active layer 352. The lower guide layer 351 is provided between the first nitride semiconductor layer 31 and the nitride semiconductor active layer 352. The upper guide layer 353 is provided between the nitride semiconductor active layer 352 and the AlGaN layer 32.

### (Lower Guide Layer)

The lower guide layer 351 is formed on the second stacked portion 312 of the first nitride semiconductor layer 31. The lower guide layer 351 has a refractive index difference from that of the second stacked portion 312 in order to confine light emitted by the nitride semiconductor active layer 352 in the light emitting portion 35. The lower guide layer 351 is formed of, for example, a mixed crystal of AlN and GaN.

Specifically, the lower guide layer 351 is formed of Alₓ₇Ga₍₁₋ₓ₇₎N (0<x7<1).

Additionally, the material for forming the lower guide layer 351 may contain a group V element other than N, such as P, As, or Sb, a group III element such as In or B, or an impurity such as C, H, F, O, Si, Cd, Zn, or Be.

An Al composition ratio x7 of the lower guide layer 351 can be identified by energy dispersive X-ray spectroscopy (EDX) of a cross-sectional structure. The Al composition ratio x7 can be defined as the ratio of the number of moles of Al to the sum of the numbers of moles of Al and Ga, and specifically can be defined using the values of the numbers of moles of Al and Ga analyzed and quantified from EDX. The Al composition ratio x7 of the lower guide layer 351 may be smaller than the Al composition ratio x6 of the second stacked portion 312. As a result, the lower guide layer 351 has a higher refractive index than that of the second stacked portion 312, which allows light emitted by the nitride semiconductor active layer 352 to be confined in the light emitting portion 35.

When the lower guide layer 351 is an n-type semiconductor, Si as a dopant is doped at a concentration of 1×10¹⁹ cm⁻³ in AlGaN to make the lower guide layer 351 n-type. When the lower guide layer 351 is a p-type semiconductor, Mg as a dopant is doped at a concentration of 3×10¹⁹ cm⁻³ in AlGaN to make the lower guide layer 351 p-type. The lower guide layer 351 may be an undoped layer that does not contain Si and Mg as dopants.

### (Nitride Semiconductor Active Layer)

The nitride semiconductor active layer 352 is a light emitting layer from which light emission of the nitride semiconductor element 1 can be obtained.

The nitride semiconductor active layer 352 is formed of, for example, AlN, GaN, and a mixed crystal thereof. More specifically, the nitride semiconductor active layer 352 is formed of, for example, Alₓ₈Ga₍₁₋ₓ₈₎N (0≤x8≤1). An Al composition ratio x8 of the nitride semiconductor active layer 352 is preferably smaller than the Al composition ratio x7 of the lower guide layer 351. As a result, carriers injected from the first electrode 14 and the second electrode 15 can be efficiently confined in the light emitting portion 35.

The nitride semiconductor active layer 352 may contain a group V element other than N, such as P, As, or Sb, a group III element such as In or B, or an impurity such as C, H, F, O, Si, Cd, Zn, or Be.

When the nitride semiconductor active layer 352 is an n-type semiconductor, Si as a dopant is doped at a concentration of 1×10¹⁹ cm⁻³ in AlGaN to make the nitride semiconductor active layer 352 n-type. When the nitride semiconductor active layer 352 is a p-type semiconductor, Mg as a dopant is doped at a concentration of 3×10¹⁹ cm⁻³ in AlGaN to make the nitride semiconductor active layer 352 p-type. The nitride semiconductor active layer 352 may be an undoped layer that does not contain Si and Mg as dopants.

The nitride semiconductor active layer 352 includes an unillustrated well layer and a barrier layer provided adjacent to the well layer. The nitride semiconductor active layer 352 may have a multiple quantum well (MQW) structure in which well layers and barrier layers are alternately stacked one by one. When the nitride semiconductor element 1 includes the nitride semiconductor active layer 352 that has a single quantum well structure, carrier density in one well layer can be increased. On the other hand, the nitride semiconductor active layer 352 may have, for example, a double quantum well structure including “barrier layer/well layer/barrier layer/well layer/barrier layer” or a triple or more quantum well structure. When the nitride semiconductor element 1 includes the nitride semiconductor active layer 352 having a multiple quantum well structure, light emission efficiency and light emission intensity of the nitride semiconductor active layer 352 can be improved. In the case of the double quantum well structure, the thickness of the well layers may be, for example, 4 nm, the thickness of the barrier layers may be, for example, 8 nm, and the thickness of the nitride semiconductor active layer 352 may be 32 nm.

The Al composition ratio of the well layer is smaller than the Al composition ratio of each of the lower guide layer 351 and the upper guide layer 353. Additionally, the Al composition ratio of the well layer is smaller than the Al composition ratio of the barrier layer. In addition, the Al composition ratio of the well layer may be the same as or different from the Al composition ratio of each of the lower guide layer 351 and the upper guide layer 353. Note that an average Al composition ratio between the well layer and the barrier layer is an Al composition ratio of the entire nitride semiconductor active layer 352. The Al composition ratios of the well layer and the barrier layer can be identified by energy dispersive X-ray spectroscopy (EDX) of a cross-sectional structure. The Al composition ratios can be each defined as the ratio of the number of moles of Al to the sum of the numbers of moles of Al and Ga, and specifically can be each defined using the values of the numbers of moles of Al and Ga analyzed and quantified from EDX.

### (Upper Guide Layer)

The upper guide layer 353 is formed on the nitride semiconductor active layer 352. The upper guide layer 353 has a refractive index difference from that of the second nitride semiconductor layer 33 in order to confine light emitted by the nitride semiconductor active layer 352 in the light emitting portion 35. The upper guide layer 353 is formed of, for example, AlN, GaN, and a mixed crystal thereof. Specifically, the upper guide layer 353 is formed of Alₓ₉Ga₍₁₋ₓ₉₎N (0≤x9≤1).

Additionally, the material for forming the upper guide layer 353 may contain a group V element other than N, such as P, As, or Sb, a group III element such as In or B, or an impurity such as C, H, F, O, Si, Cd, Zn, or Be.

An Al composition ratio X9 of the upper guide layer 353 can be identified by energy dispersive X-ray spectroscopy (EDX) of a cross-sectional structure. The Al composition ratio x9 can be defined as the ratio of the number of moles of Al to the sum of the numbers of moles of Al and Ga, and specifically can be defined using the values of the numbers of moles of Al and Ga analyzed and quantified from EDX. The Al composition ratio x9 of the upper guide layer 353 may be larger than the Al composition ratio of the well layers. This allows for carrier confinement in the nitride semiconductor active layer 352.

When the upper guide layer 353 is an n-type semiconductor, for example, Si is doped at a concentration of 1×10¹⁹ cm⁻³ in AlGaN to make the upper guide layer 353 n-type. When the upper guide layer 353 is a p-type semiconductor, for example, Mg is doped at a concentration of 3×10¹⁹ cm⁻³ in AlGaN to make the upper guide layer 353 p-type. The upper guide layer 353 may be an undoped layer.

### <Electron Block Layer>

The electron block layer 34 is provided between the light emitting portion 35 and the AlGaN layer 32. The electron block layer 34 can reflect electrons that have been poured in from the first nitride semiconductor layer 31 side and have not been injected into the nitride semiconductor active layer 352 and can inject the electrons into the nitride semiconductor active layer 352. The electrons that have not been injected into the nitride semiconductor active layer 352 are, for example, electrons that are not injected into the nitride semiconductor active layer 352 and flow to the AlGaN layer 32 side when the AlGaN layer 32 has low hole concentration. When the electrons flow to the AlGaN layer 32 side, electron injection efficiency into the nitride semiconductor active layer 352 is lowered, which makes it difficult to sufficiently improve the light emission efficiency. Providing the electron block layer 34 can improve the electron injection efficiency into the nitride semiconductor active layer 352, so that the light emission efficiency can be improved.

The electron block layer 34 is formed of, for example, AlGaN. More specifically, the electron block layer 34 is formed of Alₓ₄Ga₍₁₋ₓ₄₎N. An Al composition ratio x4 of the electron block layer 34 is, for example, preferably equal to or more than the Al composition ratio x1 of the AlGaN layer 32. The electron block layer 34 is preferably a p-type semiconductor injected with Mg. Mg is injected at a concentration of, for example, 1×10¹⁸ cm⁻³ in the electron block layer 34. This makes the electron block layer 34 p-type to form a p-type semiconductor. Mg does not have to be added into the electron block layer 34. When Mg is not added into the electron block layer 34, conductivity of the electron block layer 34 is lowered. However, particularly, in the case of a laser diode, increase in an internal loss due to absorption can be suppressed, which can reduce a threshold current density Jth.

The electron block layer 34 is required to have as high a barrier height as possible from the viewpoint of blocking electrons. However, setting the barrier height too high increases element resistance, which increases the drive voltage of the nitride semiconductor element 1, and reduces a maximum current density reachable without causing breakdown of the nitride semiconductor element 1. Therefore, preferably, the Al composition ratio of the electron block layer 34 is higher than the Al composition ratio of the nitride semiconductor active layer 352 by at least 0.3 and less than 0.55. When the Al composition ratio of the electron block layer 34 is higher than the Al composition ratio of the nitride semiconductor active layer 352 by 0.3 or more, element continuity is favorably maintained. Additionally, when the Al composition ratio of the electron block layer 34 is larger than the Al composition ratio of the nitride semiconductor active layer 352 by less than 0.55, an increase in the element resistance is suppressed.

The thickness of the electron block layer 34 is preferably from 0 nm to 50 nm, more preferably from 0 nm to 30 nm, and still more preferably from 2 nm to 20 nm. In other words, the electron block layer 34 does not have to be provided. When the thickness of the electron block layer 34 is 50 nm or less, the nitride semiconductor element 1 has low element resistance and can be driven at low voltage. Furthermore, the smaller the thickness of the electron block layer 34, the lower the element resistance of the nitride semiconductor element 1 can be. It is thus preferable that the thickness of the electron block layer 34 is smaller. In addition, when the thickness of the electron block layer 34 is 2 nm or more, it is preferable from the viewpoint of improving light emission output because internal efficiency can be improved by exhibiting the effect of blocking electrons.

The electron block layer 34 may be arranged between the nitride semiconductor active layer 352 and the upper guide layer 353. Alternatively, the electron block layer 34 may be arranged in the lower guide layer 351 so as to divide the lower guide layer 351. Alternatively, the electron block layer 34 may be arranged between the lower guide layer 351 and the nitride semiconductor active layer 352. The electron block layer 34 may be formed by a plurality of layers. The electron block layer 34 may be formed with a single Al composition or may have a superlattice structure in which large Al composition and small Al composition are repeated.

### <First Electrode>

The first electrode 14 is formed on the ridge semiconductor layer 17, i.e., on the second nitride semiconductor layer 33, which is a top layer of the ridge semiconductor layer 17.

The first electrode 14 is formed to be a p-type electrode since it is formed on the second nitride semiconductor layer 33, which is a p-type semiconductor layer. The first electrode 14 is used to inject holes into the nitride semiconductor element 1 from the first electrode 14, and is formed of a p-type electrode material for a typical nitride semiconductor element. For example, the first electrode 14 is formed of Ni, Au, Pt, Ag, Rh, Pd, Cu, or any alloy thereof, ITO, or the like, and particularly preferably formed of Ni, Au, or an alloy thereof, or ITO. This is because a contact resistance between the first electrode 14 and the ridge semiconductor layer 17 is reduced.

The first electrode 14 may include a pad electrode (a first pad electrode) on an upper part thereof in order to evenly diffuse current over the entire region of the first electrode 14. The pad electrode is formed of, for example, Au, Al, Cu, Ag, W, or the like, and preferably formed of Au from the viewpoint of conductivity. Additionally, the first electrode 14 may have a structure in which a first contact electrode formed of, for example, an alloy of Ni and Au is formed on the ridge semiconductor layer 17, and the first pad electrode formed of Au is formed on a second contact electrode.

The first electrode 14 is formed with a thickness of, for example, 240 nm.

In the case of a laser diode, the first electrode 14 may have a rectangular shape with a short side length of less than 10 μm and a long side length of 1000 μm or less, and may be stacked on the second nitride semiconductor layer 33. In the case of a light emitting diode, various shapes are assumed, but, for example, a 50 μm×200 μm rectangular shape or the like is assumed. A surface of the first electrode 14 facing the ridge semiconductor layer 17 is substantially the same in shape with the ridge semiconductor layer 17. Since the contact surfaces of the first electrode 14 and the ridge semiconductor layer 17 have the same shape as each other, the carriers injected from the first electrode 14 is suppressed from diffusing in the horizontal direction of the substrate 11 in the ridge semiconductor layer 17, so that light emission by the nitride semiconductor active layer 352 can be controlled.

### <Second Electrode>

The second electrode 15 is formed on the second stacked portion 312 of the first nitride semiconductor layer 31.

The second electrode 15 is formed to be an n-type electrode since it is formed on the first nitride semiconductor layer 31, which is an n-type semiconductor layer. The second electrode 15 is formed of an n-type electrode material for a typical nitride semiconductor light emitting element when the second electrode 15 is used to inject electrons into the first nitride semiconductor layer 31. For example, the second electrode 15 is formed of Ti, Al, Ni, Au, Cr, V, Zr, Hf, Nb, Ta, Mo, W, or any alloy thereof, ITO, or the like.

The second electrode 15 may include a pad electrode (a second pad electrode) on an upper part thereof in order to evenly diffuse current over the entire region of the second electrode 15. The pad electrode can be the same in material and configuration as the pad electrode of the first electrode 14.

The second electrode 15 is formed with a thickness of, for example, 60 nm. While the second electrode 15 in the present disclosure is formed with a thickness different from that of the first electrode 14, the second electrode 15 may be the same in thickness as the first electrode 14.

### (Resonator Surface)

When the nitride semiconductor element 1 is applied to a laser diode, it is necessary to form a resonator surface. A resonator surface 16a is formed by the same plane formed by respective one side surfaces of the second stacked portion 312 of the first nitride semiconductor layer 31, the light emitting portion 35, the electron block layer 34, the AlGaN layer 32, and the second nitride semiconductor layer 33. The resonator surface 16a is a surface whose contour is illustrated by a thick line in FIG. 1.

Additionally, a backside resonator surface 16b is a side surface opposing the resonator surface 16a, and formed by the same plane formed by respective one side surfaces of the second stacked portion 312 of the first nitride semiconductor layer 31, the light emitting portion 35, the electron block layer 34, the AlGaN layer 32, and the second nitride semiconductor layer 33. The backside resonator surface 16b is a surface whose partial contour is illustrated by a thick line in FIG. 1.

The resonator surface 16a and the backside resonator surface 16b are provided to reflect light emitted from the light emitting portion 35. In order to confine the light reflected by the resonator surface 16a and the backside resonator surface 16b in the light emitting portion 35, the resonator surface 16a and the backside resonator surface 16b are provided in pairs. The resonator surface 16a is, for example, a light emitting side of the nitride semiconductor element 1. In order to reflect light emitted from the light emitting portion 35 on the resonator surface 16a and the backside resonator surface 16b, the resonator surface 16a and the backside resonator surface 16b may be perpendicular and flat with respect to a contact surface between the light emitting portion 35 and the electron block layer 34. However, the resonator surface 16a and the backside resonator surface 16b may entirely or partially have an inclined portion or an uneven portion.

Surfaces of the resonator surface 16a and the backside resonator surface 16b may be formed with an insulating protective film such as a dielectric multilayer film and a reflective film. Specifically, the insulating protective film may be formed of SiO₂, and besides, may be formed of Al₂O₃, SiN, SnO₂, ZrO, HfO₂, or the like. Additionally, the insulating protective film may have a structure in which the materials are laminated. The insulating protective film may be formed on surfaces of both the resonator surface 16a serving as the light emitting side of the nitride semiconductor element 1 and the backside resonator surface 16b serving not as the light emitting side but as a light reflecting side. The insulating protective film formed on the resonator surface 16a on the light emitting side and the insulating protective film formed on the backside resonator surface 16b on the light reflecting side may be the same or different in structure.

### (Production Method)

The electron block layer 34 and the AlGaN layer 32 can be produced as follows. For example, using a metalorganic vapor phase epitaxy apparatus (MOVPE apparatus), AlGaN is grown by continuously increasing the flow rate of TMG (trimethylgallium) and continuously reducing the flow rate of TMA (trimethylaluminum) as raw material gases while simultaneously supplying ammonium gas. At this time, the thicknesses of the electron block layer 34 and the AlGaN layer 32 can be adjusted by adjusting the growth time of AlGaN.

As a result, there can be produced a composition change layer in which the Al composition ratio of AlGaN is changed. In this case, Mg can be added as an impurity in AlGaN by supplying Cp₂Mg (cyclopentadienyl magnesium) simultaneously with the ammonium gas.

### (Measurement Method)

Identification of the materials and the compositions in the present embodiment is performed by energy dispersive X-ray spectrometry (EDX). The arrangement of each layer is clarified by dividing and polishing a cross section perpendicular to the stacking direction of each layer or focused ion beam (FIB) processing, and observing the cross section through a transmission electron microscope (TEM), and then identified by energy dispersive X-ray spectrometry (EDX), which enables point analysis. Additionally, the film thickness of the semiconductor thin film is measured by dividing and polishing or focused ion beam processing a cross section perpendicular to a thin film stacking direction and observing the cross section through a transmission electron microscope.

### Effects of First Embodiment

The nitride semiconductor element according to the first embodiment has the following effects:

(1) The nitride semiconductor element according to the first embodiment includes the AlGaN layer formed above the nitride semiconductor active layer, the AlGaN layer being formed of AlGaN having an Al composition ratio decreasing in a direction away from the nitride semiconductor active layer.

As a result, the element 1 can be driven at high current or high current density.

(2) In the nitride semiconductor element according to the first embodiment, the AlGaN layer contains Mg, and includes the first AlGaN region in which the compositional gradient a1 of the Al composition ratio of the AlGaN layer is larger than 0 Al %/nm and smaller than 0.22 Al %/nm, and the concentration b1 of the Mg in the AlGaN layer is larger than 0 cm⁻³ and smaller than 7.0×10¹⁹×a1-2.0×10¹⁸ cm⁻³.

This can suppress the nitride semiconductor element from becoming insulated or having high resistance.

(3) The nitride semiconductor element according to the first embodiment includes the AlGaN layer in which the a-axis lattice constant c2 of the upper end surface thereof is larger than the a-axis lattice constant c1 of the lower end surface thereof.

As a result, by containing a predetermined amount of Mg, the effect of facilitating current flow can be further improved even when the AlGaN layer is so thick that lattice relaxation occurs or even when the Al composition of the AlGaN layer 32 greatly changes.

(4) The nitride semiconductor element according to the present embodiment may include the protruding portion on the surface of the AlGaN layer facing the second nitride semiconductor layer.

In this case, the contact area between the AlGaN layer and the second nitride semiconductor layer increases, which enables element driving at high current density.

### 2. Second Embodiment

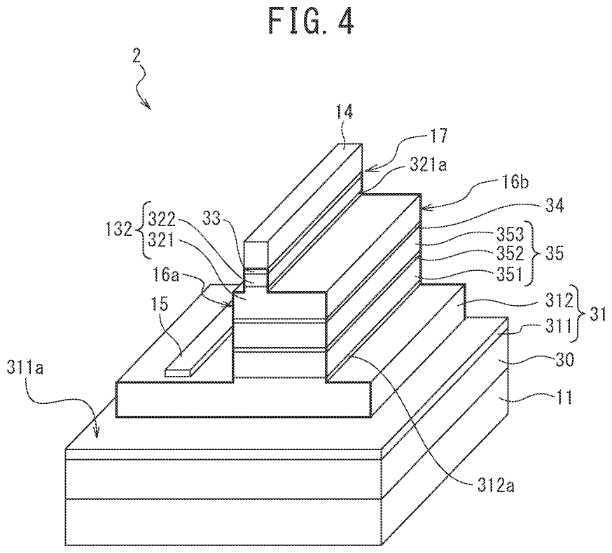

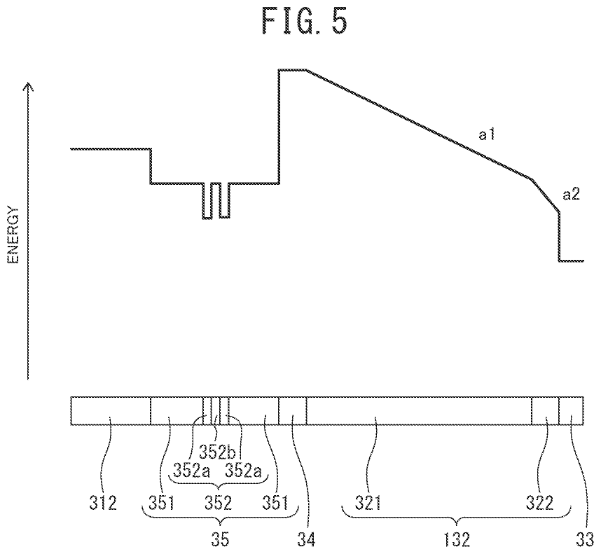

A nitride semiconductor element 2 according to a second embodiment will be described below with reference to FIGS. 4 and 5. The nitride semiconductor element 2 is an element capable of emitting ultraviolet light, similarly to the nitride semiconductor element 1.

As illustrated in FIG. 4, in the nitride semiconductor element 2, the substrate 11, the AlN layer 30, the first nitride semiconductor layer 31, the light emitting portion 35, the electron block layer 34, an AlGaN layer 132, and the second nitride semiconductor layer 33 are stacked in this order. The AlGaN layer 132 includes a plurality of regions different in Al composition ratio. The nitride semiconductor element 2 also includes the first electrode 14 provided in contact with the second nitride semiconductor layer 33 and the second electrode 15 provided in contact with a part of the first nitride semiconductor layer 31. In other words, the nitride semiconductor element 2 is different from the nitride semiconductor element 1 according to the first embodiment in that the element 2 includes the AlGaN layer 132 including the plurality of regions different in Al composition ratio, instead of the AlGaN layer 32.

The AlGaN layer 132 will be described below. A description will be given of a case where the nitride semiconductor element 2 according to the present embodiment includes the AlGaN layer 132 that includes a first AlGaN region 321 and a second AlGaN region 322, which are two layer regions different in Al composition ratio.

Note that the substrate 11, the AlN layer 30, the first nitride semiconductor layer 31, the electron block layer 34, the light emitting portion 35, and the second nitride semiconductor layer 33 other than the AlGaN layer 132 are the same in configuration as that of each component described in the first embodiment, and therefore the description thereof is omitted. Additionally, the first electrode 14 and the second electrode 15 are also the same in configuration as that of each component described in the first embodiment, and therefore description thereof is omitted.

### (First AlGaN Region)

As illustrated in FIG. 5, the first AlGaN region 321 can be configured in the same manner as the AlGaN layer 32 of the nitride semiconductor element 1 according to the first embodiment. Specifically, the first AlGaN region 321 is a p-type semiconductor formed of AlGaN containing Mg and having an Al composition ratio decreasing in a direction away from the nitride semiconductor active layer 352. In the first AlGaN region 321, the compositional gradient a1 of the Al composition ratio is larger than 0 Al %/nm and smaller than 0.22 Al %/nm. In other words, the compositional gradient a1 of the Al composition ratio is represented by 0<a1<0.22.

In addition, the first AlGaN region 321 contains Mg, which is an impurity for generating holes in the first AlGaN region 321. The concentration b1 of the Mg in the first AlGaN region 321 is larger than 0 cm⁻³ and smaller than 7.0×10¹⁹×a1-2.0×10¹⁸ cm⁻³.

The nitride semiconductor element 2 can be configured including the first AlGaN region 321 as the AlGaN layer 32 of the nitride semiconductor element 1 and a second AlGaN region 322, which will be described in the present embodiment, between the first AlGaN region 321 and the second nitride semiconductor layer 33.

### (Second AlGaN Region)

The second AlGaN region 322 is a region formed on or above the first AlGaN region 321, i.e., at a position away from the nitride semiconductor active layer 352, and is formed of AlGaN.

As illustrated in FIG. 5, the second AlGaN region 322 is a p-type semiconductor formed of AlGaN containing Mg and having an Al composition ratio decreasing in a direction away from the first AlGaN region 321. A compositional gradient a2 of the Al composition ratio of the second AlGaN region 322 is larger than the compositional gradient a1 of the first AlGaN region 321. This allows current to efficiently flow from the second AlGaN region 322 to the first AlGaN region 321. The Al composition ratio x1 of the first AlGaN region 321 may decrease at a constant rate of change in the entire area in a thickness direction of the first AlGaN region 321 or may decrease at a different rate of change depending on the position as long as the Al composition ratio x1 is within the above range.

Additionally, a concentration b2 of the Mg in the second AlGaN region 322 is larger than the concentration b1 of the Mg in the first AlGaN region 321. In the first AlGaN region 321 whose Al composition ratio is larger than that of the second AlGaN region 322, the activation energy of the Mg impurity is larger than in the second AlGaN region 322, and the amount of holes generated by addition of Mg is less than the second AlGaN region 322. On the other hand, since the second AlGaN region 322 is formed of the AlGaN having the Al composition ratio smaller than that of the first AlGaN region 321, the activation energy for hole generation by the Mg impurity is small, and the amount of holes generated by addition of Mg increases. As a result, electrons generated by the above-mentioned donor defect derived from the Mg impurity are cancelled out by holes generated by the activation of the Mg in the layer of the second AlGaN region 322, thus enabling facilitation of current flow. When the Mg concentration is within the predetermined range, electrons, although which are generated due to lattice relaxation as described above, can be cancelled out by holes generated by the activation of the Mg impurity, and it is also possible to suppress holes generated by polarization doping from being cancelled out by electrons. The lattice relaxation occurs more easily in the second AlGaN region 322, which is the upper layer, than the first AlGaN region 321 during thin-film growth. Furthermore, since the second AlGaN region 322 is smaller in Al composition ratio than the first AlGaN region 321, the activation energy by the Mg impurity is smaller, and the amount of holes generated by the Mg impurity is larger. Therefore, it is preferable that the second AlGaN region 322 has a higher Mg impurity concentration than the first AlGaN region 321.

In addition, an a-axis lattice constant c4 of an upper end surface of the second AlGaN region 322 may be larger than an a-axis lattice constant c3 of a lower end surface of the second AlGaN region 322, which is a boundary surface with the first AlGaN region 321. It is possible to suppress the occurrence of cracks due to too much stress to the second AlGaN region 322 by lattice relaxation. On the other hand, tensile stress works by the lattice relaxation, which causes local generation of electrons. In order to cancel out the electrons, it is preferable to contain Mg at a predetermined concentration. Containing the predetermined concentration of Mg leads to the activation of the Mg, which generates a considerable amount of holes, and then the electrons and the holes are cancelled each other out, whereby p-type conductivity is maintained.

In the lattice-matched first AlGaN region 321, it is preferable to ensure electrical characteristics by minimizing the amount of Mg added. On the other hand, in the lattice-relaxed second AlGaN region 322, the amount of Mg added is increased more than that in the first AlGaN region 321 to cancel out a polarization-induced electron gas by holes generated by the activation of the Mg impurity and generate more holes, thereby making the region p-type conductive. As a result, since a high concentration of holes can be generated in the layers of both the first AlGaN region 321 and the second AlGaN region 322, high current can flow, and insulation of the nitride semiconductor element 2 is unlikely to occur.

More specifically, the second AlGaN region 322 is formed of Alₓ₂Ga₍₁₋ₓ₂₎N. Preferably, an Al composition ratio x2 of the second AlGaN region 322 is represented by, for example, 0<x2≤0.45. In other words, the Al composition ratio x2 of the second AlGaN region 322 may vary from 0.45 up to almost 0 in the direction away from the nitride semiconductor active layer 352. When the second AlGaN region 322 is formed of the AlGaN having the Al composition ratio decreasing toward the upper end surface, a barrier with AlGaN forming the second nitride semiconductor layer 33 can be significantly reduced. This can further reduce a resistance between the second AlGaN region 322 and the second nitride semiconductor layer 33, and Shottky barrier is reduced, which can further improve carrier injection efficiency.

Preferably, the second AlGaN region 322 is formed to have an average Al composition ratio smaller than that of the first AlGaN region 321. This allows for efficient flow of current from the electrode to the active layer.

The AlGaN forming the second AlGaN region 322 may contain a group V element other than N, such as P, As, or Sb or an impurity such as C, H, F, O, Si, Cd, Zn, or Be.

The AlGaN forming the second AlGaN region 322 also contains Mg as a p-type semiconductor dopant. The second AlGaN region 322 is a region in which the Al composition ratio x2 continuously decreases, and during a c-plane growth, polarization induces hole generation in the second AlGaN region 322.

For example, an AlGaN layer formed of a mixed crystal of AlN and GaN having a constant composition may be included between the first AlGaN region 321 and the second AlGaN region 322.

The second AlGaN region 322 may also include a protruding portion on a surface thereof facing the second nitride semiconductor layer 33. In this case, the Al composition ratio x2 may be graded from a side of the second AlGaN region 322 facing the first AlGaN region 321 toward a leading end of the protruding portion. Including the protruding portion on the second AlGaN region 322 has the effect of improving current density when electrons are injected from the first electrode 14. In addition, including the protruding portion on the second AlGaN region 322 can increase a contact area between the second AlGaN region 322 and the second nitride semiconductor layer 33, which can reduce series resistance and pseudo energy barrier, thus allowing for reduced Schottky component and improved carrier injection efficiency.

### Effects of Second Embodiment

The nitride semiconductor element according to the second embodiment has, in addition to the effects of (1) to (4) described in the first embodiment, the following effects:

(5) The nitride semiconductor element according to the present embodiment includes the second AlGaN region having the compositional gradient a2 of the Al composition ratio larger than the compositional gradient a1 of the first AlGaN region.

This allows for efficient current flow from the second AlGaN region to the first AlGaN region. Here, the term “efficient” means that improving carrier injection efficiency can increase light emission efficiency in the light emitting element, that oscillation threshold of a laser diode can be reduced, and that element resistance of a light receiving element can be reduced.

(6) In the nitride semiconductor element according to the present embodiment, the concentration b2 of the Mg in the second AlGaN region is larger than the concentration b1 of the Mg in the first AlGaN region.

As a result, even when there is a region where electrons are generated in the AlGaN by lattice relaxation, the electrons can be cancelled out by holes generated by the activation of the Mg impurity, so that no element breakdown occurs even when driven at high current, and element driving efficiency (light emission efficiency and power conversion efficiency) can be increased.

### EXAMPLE

Hereinafter, the nitride semiconductor element according to the present disclosure will be described with Example.

In Example, nitride semiconductor elements having the configuration described in the second embodiment were produced, and electrical characteristics thereof were evaluated.

The basic configuration of each nitride semiconductor element in Example (see FIG. 4) are given below.

Note that, for example, the expression “Al_{x→y}” in the following compositions indicates that the Al composition has gradually changed from x to y from a lower layer side to an upper layer side in the layer.

### (Basic Model)

An AlN layer, a first nitride semiconductor layer, a light emitting portion including a lower guide layer, a nitride semiconductor active layer, and an upper guide layer, an electron block layer, a composition change layer (an AlGaN layer) including a first composition change region (a first AlGaN region) and a second composition change region (a second AlGaN region), and a second nitride semiconductor layer serving as a cover layer were formed on an upper surface of a substrate. Next, a first electrode provided in contact with the second nitride semiconductor layer and a second electrode provided in contact with a part of the first nitride semiconductor layer were formed. Here, each layer was formed in the following configuration.
Substrate: sapphire substrate
AlN layer: thickness 1.6 μm
First nitride semiconductor layer: composition n-Al_{0.55}Ga_{0.5}N, thickness 3 μm
Lower guide layer and upper guide layer: composition u-Al_{0.45}Ga_{0.55}N, thickness 150 nm for each
Nitride semiconductor active layer: (double quantum well structure)

Well layer: composition Al_{0.35}Ga_{0.65}N, thickness 4 μm

Barrier layer: composition Al_{0.45}Ga_{0.55}N, thickness 8 μm
Electron block layer: composition u-AlₓGa₁₋ₓN, thickness 20 nm
Composition change layer (two-layer structure)

First composition change region: composition p-Al_{x→0.45}Ga_{(1-x)→0.55}N (x represents an initial end Al composition ratio of the first composition change region), thickness 260 nm

Second composition change region: composition p-Al_{0.45→0}Ga_{0.55→1}N, Mg concentration 2.0×10¹⁹ cm⁻³, thickness 75 nm.
Second nitride semiconductor layer: composition p-GaN, thickness 10 nm
Ridge width: 5 μm
P-type electrode width: 3 μm

### <Sample 1> to <Sample 4>

As depicted in Table 1, an initial end Al composition ratio x of the first composition change region was varied from 1.0 to 0.9, 0.7, and 0.6 with a final end Al composition ratio thereof fixed at 0.45 to vary the Al compositional gradient. Additionally, the Mg concentration of the first composition change region was maintained constant at 1.0×10¹⁹ cm⁻³.

In addition, the initial end and final end Al composition ratios, respectively, of the second composition change region were set to 0.45 and 0, thereby having an Al compositional gradient of 0.6, which was larger than the compositional gradient of the first composition change region. Furthermore, the Mg concentration of the second composition change region was set to 2.0×10¹⁹ cm⁻³, which was higher than the Mg concentration of the first composition change region.

As a result, there were produced nitride semiconductor elements of samples 1 to 4 different in Al compositional gradient of the first composition change region, larger in the Al compositional gradient of the second composition change region than the Al compositional gradient of the first composition change region, and higher in the Mg concentration of the second composition change region than the Mg concentration of the first composition change region.

### <Sample 5> to <Sample 7>

As depicted in Table 1, nitride semiconductor elements of samples 5 to 7 were produced in the same manner as samples 2 to 4 except that the Mg concentration was set to 2.0×10¹⁷ cm⁻³.

As a result, the nitride semiconductor elements of samples 5 to 7 were different in Al compositional gradient of the first composition change region, larger in the Al compositional gradient of the second composition change region than the Al compositional gradient of the first composition change region, and higher in the Mg concentration of the second composition change region than the Mg concentration of the first composition change region.

### <Evaluation>

For each of the basic model nitride semiconductor elements as described above, evaluation was conducted on current-voltage (IV) characteristics when a pulse current flowed. In this case, the current-voltage characteristics were measured under the following conditions:

Pulse width: 50 nsec

Duty ratio: 0.0001

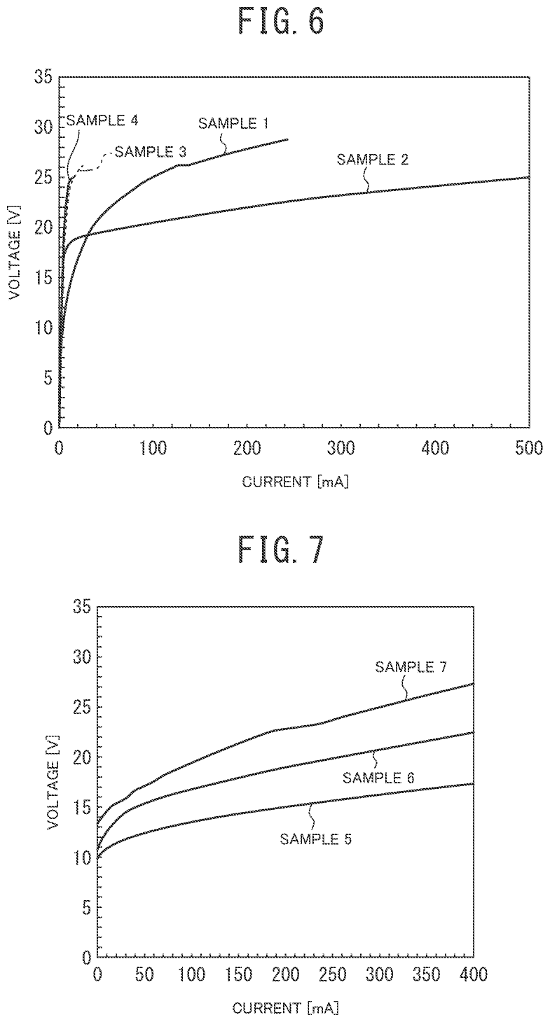

Table 1 below shows the configuration of each sample and the evaluation results of the current-voltage characteristics thereof. Table 1 also shows upper limit values of preferable ranges of Mg concentration obtained from the approximate equation A described in the first embodiment and the gradient of the Al composition ratio. Additionally, FIG. 6 illustrates the current-voltage characteristics of samples 1 to 4, and FIG. 7 illustrates the current-voltage characteristics of samples 5 to 7.

TABLE 1

| | First composition change region | | | | | Second composition change region | | | |
|---|---|---|---|---|---|---|---|---|---|
| | Initial end | Final end | Al | | Upper limit | Initial end | Final end | | |
| | Al | Al | compositional | Mg | of | Al | Al | Mg | Evaluation |
| | composition | composition | gradient | concentration | preferable | composition | composition | concentration | IV |
| | ratio X | ratio | [Al %/nm] | [cm⁻³] | range | ratio | ratio | [cm⁻³] | characteristics |
| SMP 1 | 1.0 | 0.45 | 0.2115 | 1.0 × 10¹⁹ | 1.28 × 10¹⁹ | 0.45 | 0 | 2.0 × 10¹⁹ | Conductive |
| SMP 2 | 0.9 | | 0.1731 | | 1.01 × 10¹⁹ | | | | Conductive |
| SMP 3 | 0.7 | | 0.0962 | | 4.73 × 10¹⁸ | | | | Insulated |
| SMP 4 | 0.6 | | 0.0577 | | 2.04 × 10¹⁸ | | | | Insulated |
| SMP 5 | 0.9 | | 0.1731 | 2.0 × 10¹⁷ | 1.01 × 10¹⁹ | | | | Conductive |
| SMP 6 | 0.7 | | 0.0962 | | 4.73 × 10¹⁸ | | | | Conductive |
| SMP 7 | 0.6 | | 0.0577 | | 2.04 × 10¹⁸ | | | | Conductive |

As shown in Table 1, the first composition change regions of the nitride semiconductor elements of samples 1, 2, and 5 to 7 contained Mg at concentrations not exceeding the upper limit values of the preferable ranges of Mg concentration described in the first embodiment. Therefore, as illustrated in FIGS. 6 and 7, when current was applied to the nitride semiconductor elements of samples 1, 2, and 5 to 7, voltage increased, resulting in a current flow of up to 200 mA or more. Particularly, the nitride semiconductor elements of samples 2 and 5 to 7 resulted in a current flow of up to 400 mA or more.

On the other hand, the nitride semiconductor elements of samples 3 and 4 each including the first composition change region containing Mg at a concentration exceeding the upper limit value of the preferable range of Mg concentration described in the first embodiment resulted in a current flow of only approximately 30 mA or less, as illustrated in FIG. 6. In other words, the result was that when the Al composition gradients were lowered by reducing the initial end Al composition ratios x of the first composition change regions and the Mg concentrations exceeded the preferable ranges, the first composition change regions became insulated.

Furthermore, a comparison between samples 3 and 4 and samples 6 and 7 show results that samples 6 and 7 each having the Mg concentration within the preferable range allowed for a current flow of 400 mA or more in the laser diode structure in spite of the same initial end Al composition ratios x and Al compositional gradients as those of samples 3 and 4.

The above result confirmed that the cause of insulation depended not only on the initial end Al composition ratios and the Al compositional gradients but also on the Mg concentrations. In other words, it is shown that in the nitride semiconductor elements having the configuration of the present Example, insulation of the laser diode structure is assumed to have occurred depending on the Mg-derived donor concentration.

The scope of the present disclosure is not limited to the illustrated and described illustrative embodiments, and includes all embodiments that provide advantageous effects to the intended advantageous effects of the present disclosure. Furthermore, the scope of the present disclosure is not limited to combinations of features of the invention defined by the claims, but may be defined by all desired combinations of particular features among all disclosed features.

### REFERENCE SIGNS LIST

1, 2: Nitride semiconductor element
14: First electrode
15: Second electrode
16a: Resonator surface
16b: Backside resonator surface
17: Ridge semiconductor layer
30: AlN layer
31: First nitride semiconductor layer
311: First stacked portion
311a: Upper surface
312: Second stacked portion
312a: Protruding region
32, 132: AlGaN layer
321: First AlGaN region
321a: Protruding region
322: Second AlGaN region
33: Second nitride semiconductor layer
34: Electron block layer
35: Light emitting portion
351: Lower guide layer
352: Nitride semiconductor active layer
353: Upper guide layer

1. A nitride semiconductor element comprising:
an active layer; and
an AlGaN layer formed above the active layer and formed of AlGaN, the AlGaN containing Mg and having an Al composition ratio decreasing in a direction away from the active layer, and the Al composition ratio being larger than 0.2,
wherein the AlGaN layer includes a first AlGaN region in which a compositional gradient a1 of the Al composition ratio is larger than 0 Al %/nm and smaller than 0.22 Al %/nm, and a concentration b1 of the Mg in the AlGaN layer is larger than 0 cm⁻³ and smaller than 7.0×10¹⁹×a1-2.0×10¹⁸ cm⁻³.

2. The nitride semiconductor element according to claim 1, wherein on an upper end surface of the AlGaN layer, the AlGaN is lattice-relaxed from a lower end surface of the AlGaN layer.

3. The nitride semiconductor element according to claim 1, wherein the AlGaN layer further includes a second AlGaN region formed on or above the first AlGaN region and formed of AlGaN, the AlGaN containing Mg and having an Al composition ratio decreasing in a direction away from the first AlGaN region, in which a composition gradient a2 of the Al composition ratio in the second AlGaN region is larger than the compositional gradient a1, and a concentration b2 of the Mg in the second AlGaN region is larger than the concentration b1.

4. The nitride semiconductor element according to claim 3, wherein an a-axis lattice constant c4 of an upper end surface of the second AlGaN layer is larger than an a-axis lattice constant c3 of a lower end surface of the second AlGaN layer, which is a boundary surface with the first AlGaN region.
